(19) United States
(12) Patent Application Publication
(10) Pub. No.: US 2004/0060662 A1
(43) Pub. Date: Apr. 1, 2004

(54) Inductively coupled plasma processing apparatus having internal linear antenna for large area processing

(75) Inventors: Geun-Young Yeom, Seoul (KR); Young-Joon Lee, Seoul (KR); Kyong-Nam Kim, Daejeon (KR)

Correspondence Address: FOLEY AND LARDNER, SUITE 500, 3000 K STREET NW, WASHINGTON, DC, 20007, US

(73) Assignee: Sungkyunkwan University

(21) Appl. No.: 10/412,407

(22) Filed: Apr. 14, 2003

(30) Foreign Application Priority Data
Sep. 26, 2002 (KR) 2002-58456

(51) Int. Cl. H01L 21/306

(52) U.S. Cl. 156/345.48

(57) ABSTRACT

Disclosed is an inductively coupled plasma processing apparatus having an internal antenna for large area processing and capable of improving plasma characteristics, such as plasma density and plasma uniformity while reducing plasma potential. The inductively coupled plasma processing apparatus has a plurality of linear antennas horizontally arranged at an inner upper portion of a reaction chamber while being spaced from each other by a predetermined distance and being connected to each other in series or in a row for receiving induced RF power and at least one magnet positioned adjacent to the linear antennas for creating a magnetic field perpendicularly crossing an electric field created by the linear antennas in such a manner that electrons perform a spiral movement.

### BACKGROUND OF THE INVENTION

1. Field of the Invention

The present invention relates to an inductively coupled plasma processing apparatus, and more particularly to an inductively coupled plasma processing apparatus, in which a linear antenna creating an electric field and a permanent magnet creating a magnetic field are simultaneously accommodated in a reaction chamber for carrying out a plasma etching process over a large area.

2. Description of the Related Art

It is very important to uniformly form plasma over a large area when performing a semiconductor device manufacturing process and a flat panel display (FPD) device manufacturing process. Recently, a silicon wafer having a diameter of 300 mm is widely utilized and a substrate of the flat panel display device has an enlarged area about 400 cm² to 1 m². Particularly, when performing a plasma etching process for fabricating a flat plasma display device including a thin film transistor liquid crystal display (TFT-LCD), superior plasma uniformity, high plasma density and low plasma potential are required to improve etching uniformity, etching rate, and etching selectivity and to prevent a semiconductor device from being damaged and contaminated.

Generally, an inductively coupled plasma (ICP) processing apparatus includes a spiral type antenna, which is installed at an upper outer portion of a reaction chamber by interposing dielectric material between the spiral type antenna and the reaction chamber performing a plasma etching process. When radio frequency power is applied to the spiral type antenna, an electric field is created in the reaction chamber, thereby generating plasma in the reaction chamber. The ICP processing apparatus has a simple structure as compared with an ECR (Electron cyclotron resonance) plasma processing device and an HWEP (Helicon-wave excited plasma) processing device. That is, the ICP processing apparatus can generate plasma over a large area in a relatively simple manner, so the ICP processing apparatus is widely used and developed.

However, a conventional ICP processing apparatus is only adapted for etching a silicon wafer having a diameter of 200 mm or 300 mm. That is, the conventional ICP processing system is not adapted for etching a flat panel display device having a large area of 730×920 mm, since plasma density is unevenly formed in a radial direction thereof due to a standing wave effect. In addition, as induced voltage applied over the large area is increased, a capacitive coupling is increased. Furthermore, it is required to form thick dielectric material between an antenna and a reaction chamber, so that the manufacturing process of the ICP processing apparatus is complicated while increasing the manufacturing cost thereof. In addition, since plasma is far remote from the antenna, power transfer efficiency is reduced.

To solve the above problems of the conventional ICP processing apparatus, there have been suggested ICP processing apparatuses having a loop type or a linear type antenna accommodated in a reaction chamber forming plasma therein. However, the above ICP processing apparatuses have a disadvantage that the antenna is contaminated during a sputtering process. In addition, unstable arcing is generated due to high plasma potential, so plasma uniformity and plasma density are deteriorated.

### SUMMARY OF THE INVENTION

The present invention has been made to solve the above problems of the conventional ICP processing apparatus, therefore, it is an object of the present invention to provide an ICP processing apparatus having an internal antenna for large area processing and capable of improving plasma characteristics, such as plasma density and plasma uniformity while reducing plasma potential.

To achieve the object of the present invention, there is provided an inductively coupled plasma processing apparatus for a large area processing, the inductively coupled plasma processing apparatus comprising: a reaction chamber; a plurality of linear antennas horizontally arranged at an inner upper portion of the reaction chamber while being spaced from each other by a predetermined distance for receiving induced RF power; and at least one magnet positioned adjacent to the linear antennas for creating a magnetic field perpendicularly crossing an electric field created by the linear antennas in such a manner that electrons perform a spiral movement.

The linear antennas are linearly arranged in the reaction chamber in parallel to each other and connected to each other at an external portion of the reaction chamber. The linear antennas can be integrally formed with each other or can be continuously connected to each other at the external portion of the reaction chamber in a zigzag pattern. In addition, the linear antennas can be divided in to several groups. The linear antennas included in each group are integrally connected to each other, and adjacent groups of the linear antennas are continuously connected to each other in a zigzag pattern.

Preferably, the linear antennas include a horizontal part formed in the reaction chamber and a bending part at an external portion of the reaction chamber. The horizontal part and the bending part are sequentially arranged at least one time. The linear antennas can be integrally formed or fabricated by connecting a plurality of linear antennas to each other.

The magnet is horizontally positioned below linear antennas and arranged between two linear antennas adjacent to each other. The magnet has a linear shape corresponding to a shape of the linear antennas. According to preferred embodiment of the present invention, a plurality of magnets are provided in such a manner that adjacent two magnets have poles different from each other. The magnets can be grouped in such a manner that adjacent two groups have poles different from each other.

According to the present invention, the electric field and the magnetic field are created over a large area of the reaction chamber. Thus, a collision probability between electrons and neutrons are increased due to a spiral movement of electrons, so stability and uniformity of plasma can be improved. In addition, required plasma density can be obtained by adjusting RF induced power. Since electron loss is minimized, the electron temperature is lowered so that low plasma potential can be obtained.

### BRIEF DESCRIPTION OF THE DRAWINGS

The above object and other advantages of the present invention will become more apparent by describing in detail preferred embodiments thereof with reference to the attached drawings in which:

FIG. 1 is a schematic view showing an ICP processing apparatus according to one embodiment of the present invention;

FIG. 2 is a partially cut-away perspective view showing a linear antenna accommodated in a reaction chamber of the ICP processing apparatus shown in FIG. 1;

FIG. 3 is a schematic view showing a relationship between an electric field and a magnetic field in the ICP processing apparatus shown in FIG. 1;

FIG. 4 is a graph showing a relationship between ion density and induced power measured in order to check whether plasma is stably generated in the ICP processing apparatus according to the present invention;

FIG. 5 is a graph showing a relationship between RF power and ion density in the ICP processing apparatus according to the present invention, which is varied depending on an existence of a magnet;

FIG. 6 is a graph showing a relationship between RF power and electron temperature in the ICP processing apparatus according to the present invention, which is varied depending on an existence of a magnet; and

FIG. 7 is a graph showing ion saturation current measured from each measuring position of the ICP processing apparatus in order to inspect plasma uniformity generated in the ICP processing apparatus according to the present invention.

### DETAILED DESCRIPTION OF THE PREFERRED EMBODIMENTS

Hereinafter, preferred embodiments of the present invention will be described in detail with reference to accompanying drawings. The preferred embodiments described below will not limit the scope of the present invention, but show examples of the present invention.

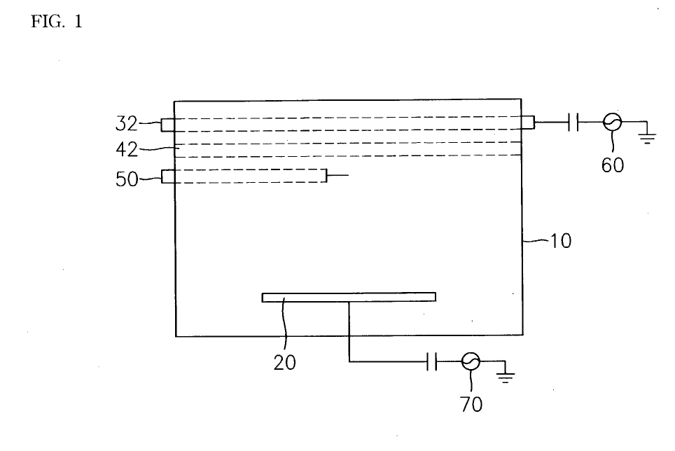

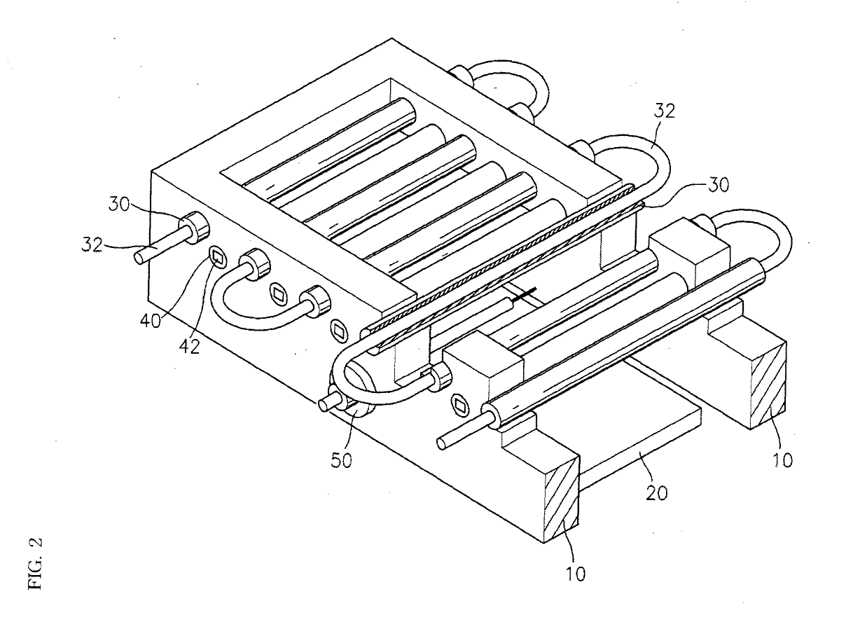

FIG. 1 is a schematic view showing an ICP processing apparatus according to one embodiment of the present invention and FIG. 2 is a partially cut-away perspective view showing a linear antenna accommodated in a reaction chamber of the ICP processing apparatus shown in FIG. 1.

Referring to FIGS. 1 and 2, a stage 20 is installed at a lower portion of a reaction chamber 10 in order to place a substrate (not shown) thereon in such a manner that a plasma etching process or a deposition process is carried out with respect to the substrate. Preferably, the stage 20 moves up and down and can be formed as an electrostatic chuck. An exhaust line connected to a vacuum pump (not shown) is formed at a bottom wall or at a part of a sidewall of the reaction chamber 10. A bias power section 70 is connected to the stage 20 in order to apply bias power to the stage. A bias voltage-measuring device (not shown) is installed on the stage 20 in order to measure bias voltage.

An inner upper portion of the reaction chamber 10 is a plasma source region, in which a plurality of linear antennas 32 are horizontally arranged adjacent to each other. The linear antennas 32 are linearly aligned in the reaction chamber 10. However, the linear antennas 32 are bent at an external portion of the reaction chamber 10 and connected to each other in series.

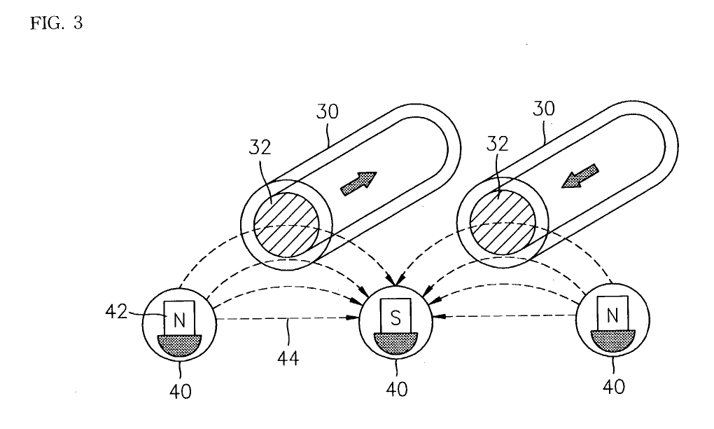

As shown in FIG. 3, permanent magnets 42 are arranged below the linear antennas 32. The permanent magnets 42 are surrounded by magnet protecting tubes 40, which are made of maternal having a superior resistance against a sputtering process, such as quartz. A Langmuir probe 50 is installed below the linear antennas 32. Langmuir probe 50 is protruded from a sidewall of the reaction chamber 10.

In order to use the reaction chamber 10 for fabricating a large area FPD, the reaction chamber 10 is made of stainless steel having a hexagonal shape with a size of 830×1020 MM. Six linear antennas 32 are inserted into the reaction chamber 10. The linear antennas 32 are connected to each other in series at the external portion of the reaction chamber 10 and each linear antenna 32 is inserted into the antenna protecting tube 30 in the reaction chamber 10. The antenna protecting tube 30 includes a quartz pipe having a superior endurance against the sputtering process. Preferably, an outer diameter of the quartz pipe is about 15 mm and thickness of the quartz pipe is about 2 mm. The linear antenna 32 is made of copper having a diameter about 10 mm. One end of the linear antenna 32 is grounded and the other end of the linear antenna 32 is connected to an RF induced power section 60 of 13.56 MHz for an induced discharge. Selectively, the linear antenna 32 can be fabricated by using stainless steel, silver, or aluminum.

In addition, the Langmuir probe 50 is available from Hiden Analytical Inc., Great Britain. The Langmuir probe 50 measures plasma characteristic such as plasma density, plasma uniformity and plasma potential from the IPC processing apparatus having internal linear antennas according to the present invention. Argon gas is used for monitoring the plasma characteristics. The Langmuir probe 50 is downwardly remote from the linear antenna 32 by a predetermined distance of 17 cm or 5 cm.

FIG. 3 is a schematic view showing a relationship between an electric field and a magnetic field in the ICP processing apparatus shown in FIG. 1.

Referring to FIG. 3, since linear antennas 32, which are adjacent to each other, are connected to each other at the external portion of the reaction chamber 10 in series, current flows (shown in FIG. 3 as arrow) in two adjacent linear antennas 32 are opposite to each other, so the directions of electric fields induced by the current flows are downwardly formed at middle parts of two adjacent linear antennas 32. In addition, since an N-pole and an S-pole of permanent magnets 42 installed below the linear antennas 32 are alternately arranged, a direction of magnetic filed created by magnetic lines 44 positioned between the permanent magnets 42 is perpendicularly crossing the electric field. In addition, electrons perform a spiral movement through the magnetic field and the electric field. That is, a moving route of electrons is enlarged through the magnetic field and the electric field, so that a collision probability between neutrons and electrons is increased. As the collision probability between neutrons and electrons is increased due to the electrons spirally moved in the magnetic field, ion density is increased and a mobility of electrons is lowered, thereby reducing an electron loss.

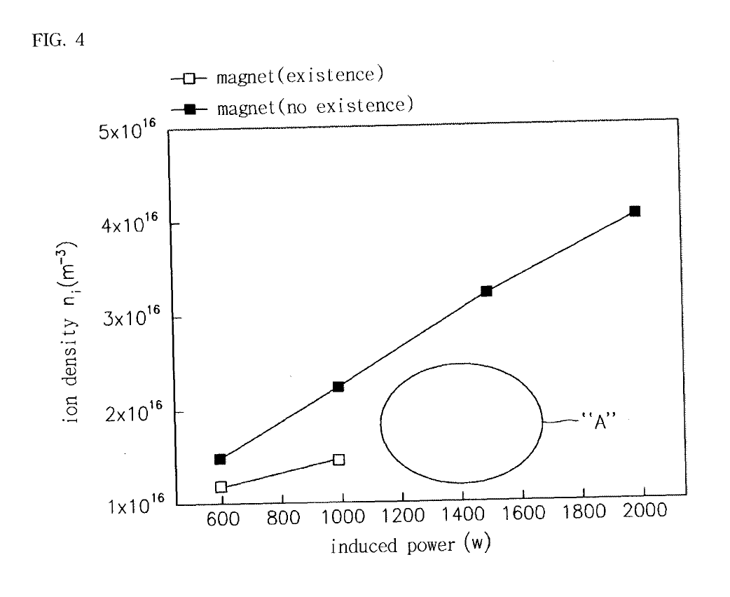

FIG. 4 is a graph showing a relationship between ion density and induced power measured in order to check whether plasma is stably generated in the ICP processing apparatus according to the present invention. Data shown in FIG. 4 are obtained when the Langmuir probe 50 is positioned below the linear antenna 32 by a distance of 17 cm. As a result of measuring ion density according to induced power applied to the induced power section 60 shown in FIG. 1, ion density is proportionally increased as induced power increases if the permanent magnet 42 is arranged adjacent to the linear antenna 32, so that plasma is stably generated. However, if the permanent magnet 42 is not arranged adjacent to the linear antenna 32, a great electron loss occurs so that an arcing is created between a wall of the reaction chamber and plasma in “A” region, in which induced power exceeds 1000W. Accordingly, it is impossible to stably generating plasma and to measure ion density.

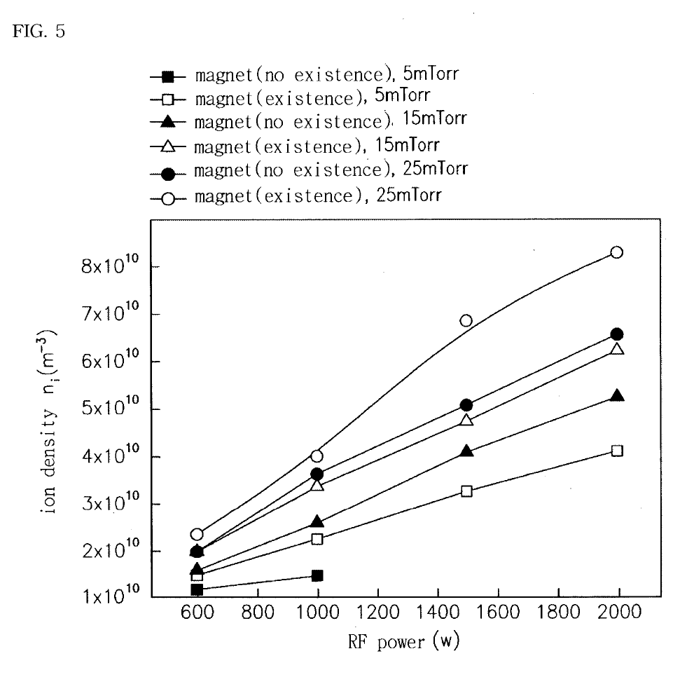

FIG. 5 is a graph showing a relationship between RF power and ion density in the ICP processing apparatus according to the present invention, which is varied depending on an existence of a magnet.

FIG. 5 shows an affect of RF induced power, operating pressure, magnetic field applied to the linear antenna 32 depending on ion density measured by the Langmuir probe 50 using argon gas when operating pressure is 5 mTorr, 15 mTorr and 25 mTorr, and RF induced power is 600 to 2000W. Six linear antennas 32 are used and the whole length of the linear antennas is 7.89 m. In addition, a distance between two adjacent antennas 32 is 11.4 cm and the Langmuir probe 50 is positioned below the linear antenna 32 by a distance of 17 cm.

As is understood from FIG. 5, ion density is linearly increased as operating pressure of argon gas and RF induced power increase. Generally, ion density is increased about 50% due to the magnetic field, which is perpendicularly crossing the electric field created by antenna current. That is, in case the permanent magnet 42 is arranged adjacent to the linear antenna when RF induced power is 2000W and argon gas pressure is 25 mTorr, ion density is 8.2×10¹⁰ cm⁻³, which is closed to 10¹¹ cm⁻³. FIG. 5 shows a measuring result when the Langmuir probe 50 is positioned below the antenna 32 by a distance of 17 cm. Ion density measured by the Langmuir probe 50 positioned below the antenna 32 by a distance of 5 cm is increased twice.

Accordingly, if RF power exceeding 1500W is applied, high-density plasma above 10¹¹ cm⁻³ is generated. If operating pressure of argon gas is 5 mTorr, an arcing is generated when RF power exceeding 1000W is applied.

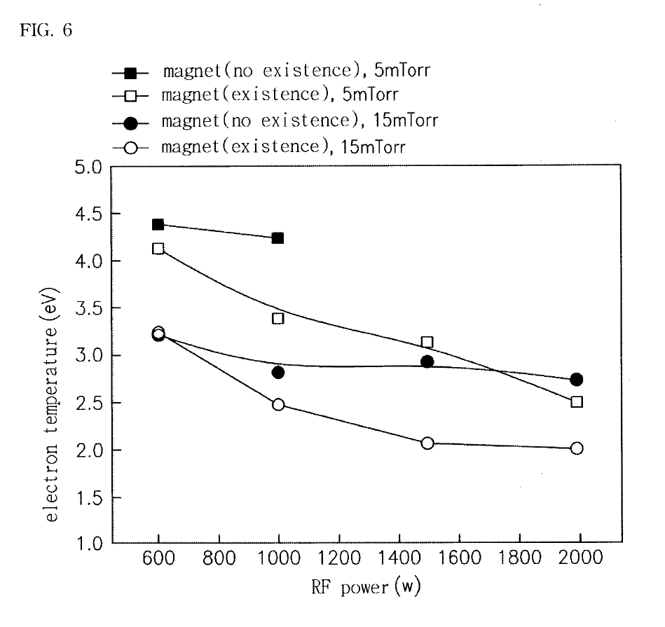

FIG. 6 is a graph showing a relationship between RF power and an electron temperature in the ICP processing apparatus according to the present invention, which is varied depending on an existence of a magnet.

FIG. 6 shows an affect of RF induced power, operating pressure of argon gas, and a magnetic field applied to the antenna 32 with respect to ion density measured by the Langmuir probe 50 using argon gas. The measurement is carried out under operating pressure of argon gas of 5 mTorr and 15 mTorr and RF induced power of 600W to 2000W in absence and existence of the permanent magnet.

As shown in FIG. 6, the electron temperature is within a range of 2.0 to 4.5 eV, and is slightly reduced as RF power increases. In addition, as operating pressure increases, the electron temperature is reduced. The electron temperature is varied depending on the existence of the permanent magnet 42. That is, when the permanent magnet 42 exists, the electron temperature is reduced.

In absence of the permanent magnet 42, if electron loss is increased due to collision between electrons and neutrons, the electron temperature has to be increased in order to maintain a plasma state. If the electron temperature is increased at low operating pressure of argon gas in absence of the permanent magnet 42, electron loss is increased.

Although it is not illustrated in the graph, plasma potential is also measured. Plasma potential is within a range of 25 to 45V, which is reduced as RF power and operating pressure of argon gas increase. However, the magnetic field does not exert a great affect to plasma potential.

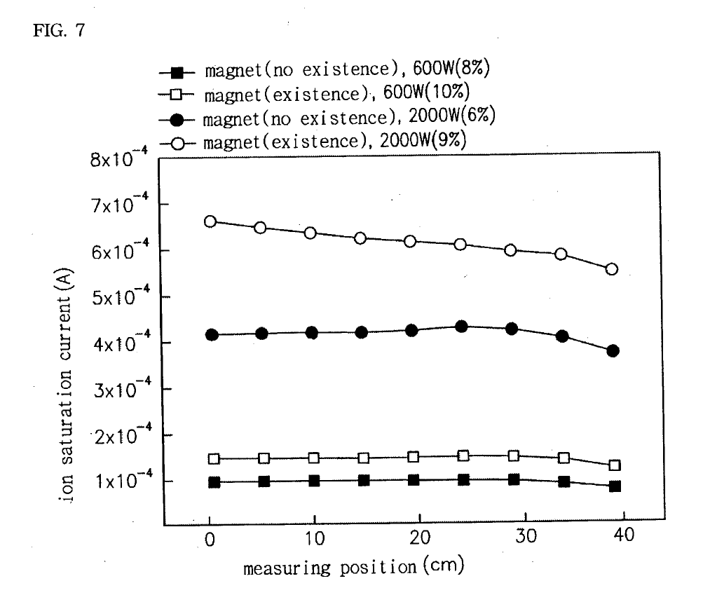

FIG. 7 is a graph showing ion saturation current measured from each measuring position of the ICP processing apparatus in order to inspect plasma uniformity generated in the ICP processing apparatus according to the present invention. Ion saturation current is used to measure plasma density.

In FIG. 7, ion saturation current is measured along a line of the antenna 32 as a function of a position of the reaction chamber by the Langmuir probe 50 positioned below the antenna 32 by a distance of 5 cm. The measurement is carried out under operating pressure of argon gas of 15 mTorr and RF induced power of 600W to 2000W in absence and existence of the permanent magnet.

As shown in FIG. 7, as RF power increases from 600 to 2000W, plasma density is increased. In addition, capacitively coupled plasma is changed to inductively coupled plasma so that plasma uniformity is improved. In absence of the permanent magnet, 6% of plasma uniformity is obtained along a position remote from a center of the reaction chamber by a distance of 40 cm. When the magnetic field is created in the reaction chamber, plasma density is increased and plasma uniformity is improved as RF power increases. Although the magnetic field increases plasma density in the reaction chamber, non-uniformity of plasma in the reaction chamber maintains below 10%. If an alignment of the magnetic field is optimized, uniformity of plasma can be further improved.

As described above, in order to carry out a large area plasma process, an internal linear antenna and a permanent magnet are accommodated in a reaction chamber in such a manner that an electric field is perpendicularly crossing a magnetic field in a plasma creating area of the reaction chamber. Accordingly, a moving route of electrons is enlarged due to a spiral movement of electrons so that a collision probability between electrons and neutrons is increased. Therefore, as RF power increases, plasma density is increased, the electron temperature is reduced and stability of plasma is improved. In addition, plasma uniformity is maintained within 10%, which is adapted for a large area plasma process.

While the present invention has been described in detail with reference to the preferred embodiments thereof, it should be understood to those skilled in the art that various changes, substitutions and alterations can be made hereto without departing from the scope of the invention as defined by the appended claims.

What is claimed is:

1. An inductively coupled plasma processing apparatus for a large area processing, the inductively coupled plasma processing apparatus comprising:
a reaction chamber;
a plurality of linear antennas horizontally arranged at an inner upper portion of the reaction chamber while being spaced from each other by a predetermined distance for receiving induced RF power; and
at least one magnet positioned adjacent to the linear antennas for creating a magnetic field perpendicularly crossing an electric field created by the linear antennas in such a manner that electrons perform a spiral movement.

2. The inductively coupled plasma processing apparatus as claimed in claim 1, wherein the linear antennas are linearly arranged in the reaction chamber in parallel to each other and connected to each other at an external portion of the reaction chamber.

3. The inductively coupled plasma processing apparatus as claimed in claim 2, wherein the linear antennas are integrally formed with each other at the external portion of the reaction chamber.

4. The inductively coupled plasma processing apparatus as claimed in claim 2, wherein adjacent linear antennas exposed out of the reaction chamber are continuously connected to each other in a zigzag pattern.

5. The inductively coupled plasma processing apparatus as claimed in claim 2, wherein the linear antennas are divided into several groups, linear antennas included in each group are integrally connected to each other, and adjacent groups of the linear antennas are continuously connected to each other in a zigzag pattern.

6. The inductively coupled plasma processing apparatus as claimed in claim 1, wherein the linear antennas include a horizontal part formed in the reaction chamber and a bending part at an external portion of the reaction chamber, the horizontal part and the bending part being sequentially arranged at least one time.

7. The inductively coupled plasma processing apparatus as claimed in claim 1, wherein the linear antennas are integrally formed or fabricated by connecting a plurality of linear antennas to each other.

8. The inductively coupled plasma processing apparatus as claimed in claim 1, wherein one end of the linear antenna is grounded.

9. The inductively coupled plasma processing apparatus as claimed in claim 1, wherein the linear antennas are surrounded by antenna protecting tubes made of quartz.

10. The inductively coupled plasma processing apparatus as claimed in claim 1, wherein the linear antennas are fabricated by any one selected from the group consisting of copper, stainless steel, silver and aluminum.

11. The inductively coupled plasma processing apparatus as claimed in claim 1, wherein the magnet is horizontally positioned below linear antennas and arranged between two linear antennas adjacent to each other.

12. The inductively coupled plasma processing apparatus as claimed in claim 1, wherein the magnet has a linear shape corresponding to a shape of the linear antennas.

13. The inductively coupled plasma processing apparatus as claimed in claim 1, wherein a plurality of magnets are provided in such a manner that adjacent two magnets have poles different from each other.

14. The inductively coupled plasma processing apparatus as claimed in claim 12, wherein a plurality of magnets are provided in such a manner that adjacent two magnets have poles different from each other.

15. The inductively coupled plasma processing apparatus as claimed in claim 1, wherein the magnet is surrounded by a magnet protecting tube made of quartz.
